(19) United States
(12) Patent Application Publication
(10) Pub. No.: US 2026/0322079 A1
(43) Pub. Date: Oct. 15, 2026

(54) SEMICONDUCTOR LIGHT-EMITTING DEVICE

(71) Applicant: FURUKAWA ELECTRIC CO., LTD., Tokyo (JP)

(72) Inventors: Akihiro IMAMURA, Tokyo (JP); Noriyuki YOKOUCHI, Tokyo (JP); Takuma YOSHIDA, Tokyo (JP)

(73) Assignee: FURUKAWA ELECTRIC CO., LTD., Tokyo (JP)

(21) Appl. No.: 19/698,336

(22) Filed: Jun. 4, 2026

Related U.S. Application Data
(63) Continuation of application No. PCT/JP2025/002325, filed on Jan. 24, 2025.

(30) Foreign Application Priority Data
Feb. 13, 2024 (JP) 2024-019234

(51) Int. Cl. H01S 5/343; H01S 5/227

(52) U.S. Cl. CPC H01S 5/3434; H01S 5/227

(57) ABSTRACT

A semiconductor light-emitting device includes a substrate made of InP, and an active layer that is positioned on the substrate. The active layer includes a Type-II heterojunction structure based on a first-type layer made of AlₓIn_{y}Ga_{(1-x-y)}AS_{z}P_{(1-z)} (where 0<x, 0<y, 0≤1-x-y, and 0<z≤1 hold true), and a second-type layer made of InᵥGa₍₁₋ᵥ₎ASwP_{(1-w)} (where 0<v≤1 and 0≤w<1 hold true). The conduction band minimum energy of the second-type layer is lower than the conduction band minimum energy of the first-type layer. The valence band maximum energy of the first-type layer is higher than the valence band maximum energy of the second-type layer. The first-type layer constitutes a quantum well layer for electron holes, and the second-type layer constitutes a quantum well layer for electrons.

### CROSS-REFERENCE TO RELATED APPLICATIONS

This application is a continuation of International Application No. PCT/JP2025/002325, filed on Jan. 24, 2025 which claims the benefit of priority of the prior Japanese Patent Application No. 2024-019234, filed on Feb. 13, 2024, the entire contents of which are incorporated herein by reference.

### BACKGROUND

The present disclosure relates to a semiconductor light-emitting device.

A semiconductor light-emitting device is used as, for example, a light source that outputs a signal light for optical communication. In optical communication, there are times when a semiconductor light-emitting device is required to perform high-temperature operations. In a semiconductor light-emitting device, the Auger recombination of electrons and electron holes in the active layer is the limiting factor in regard to performing high-temperature operations. In that regard, in G. G. Zegrya and A. D. Andreev “Mechanism of suppression of Auger recombination processes in type-II heterostructures” Applied Physics Letters vol. 67, Issue 18, pp. 2681-2683, 1995, it is disclosed that a quantum well that is formed based on the Type-II heterojunction structure is used to appropriately adjust the band offset between the conduction band and the valence band, so that a reduction in the Auger recombination can be theoretically predicted. In the following explanation, a quantum well that is formed based on the Type-II heterojunction structure is sometimes referred to as a Type-II quantum well.

Regarding a Type-II quantum well, for example, in Japanese Unexamined Patent Application Publication (Translation of PCT application) No. H9-510831, quantum well are disclosed that include a Type-II quantum well based on a, II-VI compound semiconductor; a Type-II quantum well based on a III-V compound semiconductor, and a Type-II quantum well based on a IV compound semiconductor. In Japanese Unexamined Patent Application Publication (Translation of PCT application) No. H9-510831, it is mentioned that the emission of light at the wavelengths of the 1.3 μm band and 1.55 μm band occurs based on a GaAsSb/InGaAs Type-II quantum well formed on a GaAs substrate. Moreover, it is mentioned that the emission of light between the wavelengths of about 2 μm and 5 μm occurs based on a GaAsSb/InGaAs Type-II quantum well formed on an InP substrate.

Japanese Patent Application Laid-open No. 2003-142783 discloses a structure by which, in a Type-II quantum well made of two electron wells and a single electron-hole well, the overlapping of the wave functions for electrons is increased by concatenating the wave functions. Moreover, it is given that the electron-hole well layer is formed to have less thickness, so that the film thickness-weighted average strain can be reduced to be approximately equal to or lower than 2%.

### SUMMARY

As explained above, in Japanese Unexamined Patent Application Publication (Translation of PCT application) No. H9-510831, it is mentioned that the emission of light between the wavelengths of about 2 μm and 5 μm occurs based on a GaAsSb/InGaAs Type-II quantum well that is formed on an InP substrate. However, there is no implementation of the wavelength used in the optical communication of the 1.3 μm band. Moreover, regarding a semiconductor alloy such as GaAsSb/InGaAs containing Sb, a semiconductor alloy exhibiting lattice matching with the InP substrate is unstable as far as the free energy is concerned, and is prone to cause phase separation. Hence, a semiconductor alloy having the abovementioned composition faces difficulty in achieving crystal growth and is difficult to manufacture.

It is desirable to at least partially solve the problems in the related art.

According to an embodiment of the present disclosure, there is provided a semiconductor light-emitting device including: a substrate made of InP; and an active layer that is positioned on the substrate, wherein the active layer includes a Type-II heterojunction structure based on a first-type layer made of AlₓIn_{y}Ga_{(1-x-y)}AS_{z}P_{(1-z)} (where 0<x, 0<y, 0≤1-x-y, and 0<z≤1 hold true), and a second-type layer made of In_{y}Ga₍₁₋ᵥ₎AS_{w}P_{(1-w)} (where 0<v≤1 and 0≤w<1 hold true), conduction band minimum energy of the second-type layer is lower than conduction band minimum energy of the first-type layer, valence band maximum energy of the first-type layer is higher than valence band maximum energy of the second-type layer, the first-type layer constitutes a quantum well layer for electron holes, and the second-type layer constitutes a quantum well layer for electrons.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic cross-sectional view of a semiconductor light-emitting device according to a first embodiment;

FIG. 2 is a diagram illustrating an example of the structure of an active layer illustrated in FIG. 1 and illustrating an example of the energy bands;

FIG. 3 is a diagram illustrating the spinodal curve of a ternary semiconductor alloy or a quaternary semiconductor alloy;

FIG. 4 is a diagram illustrating the relationship between the conduction band minimum energy and the valence band maximum energy of the alloys that exhibit lattice matching with InP;

FIG. 5 is a diagram illustrating an example of the structure of the active layer and illustrating an example of the energy bands in the semiconductor light-emitting device according to a second embodiment;

FIG. 6 is a diagram illustrating an example of the structure of the active layer and illustrating an example of the energy bands in the semiconductor light-emitting device according to a third embodiment;

FIG. 7 is a diagram illustrating the relationship between the conduction band minimum energy and the valence band maximum energy of an active layer according to the third embodiment;

FIG. 8 is a diagram illustrating an example of the structure of the active layer and illustrating an example of the energy bands in the semiconductor light-emitting device according to a fourth embodiment;

FIG. 9 is a diagram illustrating an example of the structure of the active layer and illustrating an example of the energy bands in the semiconductor light-emitting device according to a fifth embodiment;

FIG. 10 is a diagram illustrating an example of the structure of the active layer and illustrating an example of the energy bands in the semiconductor light-emitting device according to a sixth embodiment;

FIG. 11 is a diagram illustrating the relationship between the conduction band minimum energy and the valence band maximum energy of an active layer according to the sixth embodiment; and

FIG. 12 is a schematic cross-sectional view of a semiconductor light-emitting device according to a seventh embodiment.

### DETAILED DESCRIPTION OF THE PREFERRED EMBODIMENTS

Exemplary embodiments of the present disclosure are described below with reference to the accompanying drawings. However, the present technique is not limited by the embodiments described below. In the drawings, identical or corresponding constituent elements are referred to by the same reference numerals, and their explanation is not given repeatedly. Meanwhile, the drawings are schematic in nature, and it needs to be noted that the relationship among the dimensions of the constituent elements or the proportion of the constituent elements may be different than the actual situation. Among the drawings too, sometimes the relationship among the dimensions and the proportion can be different.

### First Embodiment

### Overall Configuration of a Semiconductor Light-Emitting Device

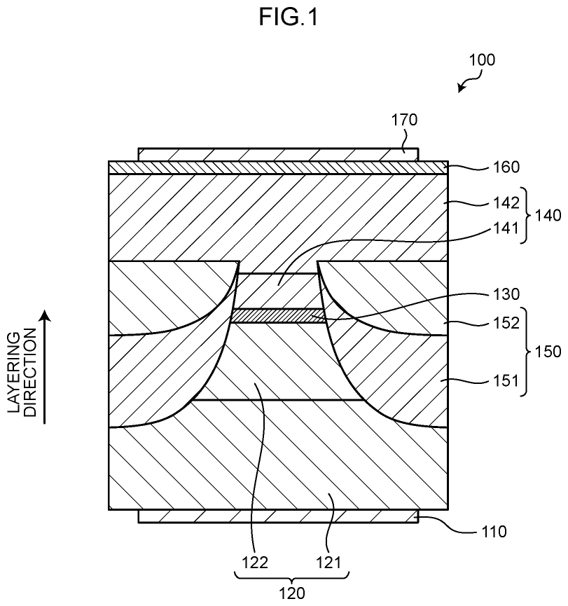

FIG. 1 is a schematic cross-sectional view of a semiconductor light-emitting device according to a first embodiment. A semiconductor light-emitting device 100 is configured as a semiconductor laser device. The semiconductor light-emitting device 100 includes: an n-type semiconductor portion 120 having an n-side electrode 110 formed on the reverse side thereof; an active layer 130; a p-type semiconductor portion 140; a current blocking layer 150; a contact layer 160; and a p-side electrode 170. The semiconductor light-emitting device 100 outputs a laser light from the active layer 130 in the perpendicular direction to the plane of FIG. 1.

The n-type semiconductor portion 120 includes a substrate 121 and includes an n-type cladding layer 122 that is positioned on the substrate 121 with the layering direction facing upward.

The substrate 121 is made of an n-type InP (hereinafter, referred to as n-InP). The n-type cladding layer 122 is made of n-InP and is layered on the substrate 121 as a result of epitaxial growth.

In the present written description, an n-type semiconductor layer includes, for example, silicon (Si), sulfur (S), or selenium (Se) as the n-type impurity. However, there is no particular restriction on the n-type impurity.

The active layer 130 is positioned on the substrate 121. Regarding the structure and the characteristics of the active layer 130, the detailed explanation is given later.

The p-type semiconductor portion 140 has a layered structure including semiconductor layers 141 and 142 made of a p-type InP (hereinafter, referred to as p-InP).

In the present written description, a p-type semiconductor includes, for example, zinc (Zn) as the p-type impurity. However, there is no particular restriction on the p-type impurity.

Herein, some part of the n-type semiconductor portion 120, the active layer 130, and some part of the p-type semiconductor portion 140 have the stripe mesa structure. In the stripe mesa structure, the width suitable for guiding the light, which is emitted from the active layer 130, in the single mode (for example, the width of 2 μm) is provided by performing etching. Both sides of the stripe mesa structure (i.e., the left and right directions with reference to FIG. 1) are buried with the current blocking layer 150 that is formed as a result of layering of a current blocking layer 151 made of p-InP and a current blocking layer 152 made of n-InP. Moreover, the semiconductor layer 142 is formed to cover the semiconductor layer 141 and the current blocking layer 150.

The contact layer 160 is made of, for example, p-type GaInAs, and makes ohmic contact with the p-side electrode 170. The p-side electrode 170 includes, for example, titanium, platinum, or gold.

The n-side electrode 110 is disposed to make ohmic contact with the substrate 121. The n-side electrode 110 includes, for example, gold or nickel.

Of the semiconductor light-emitting device 100, both end faces parallel to the plane of FIG. 1 are made of cleavages. On one of those end faces is formed a high reflection (HR) film having a relatively high reflectance. On the other end face is formed an anti-reflection (AR) film used for preventing reflection. The HR film and the AR film constitute a laser cavity. In the semiconductor light-emitting device 100, when an electric current is injected from the p-side electrode 170, a laser light is output mainly from the end face having the AR film formed thereon.

### Structure and Characteristics of Active Layer

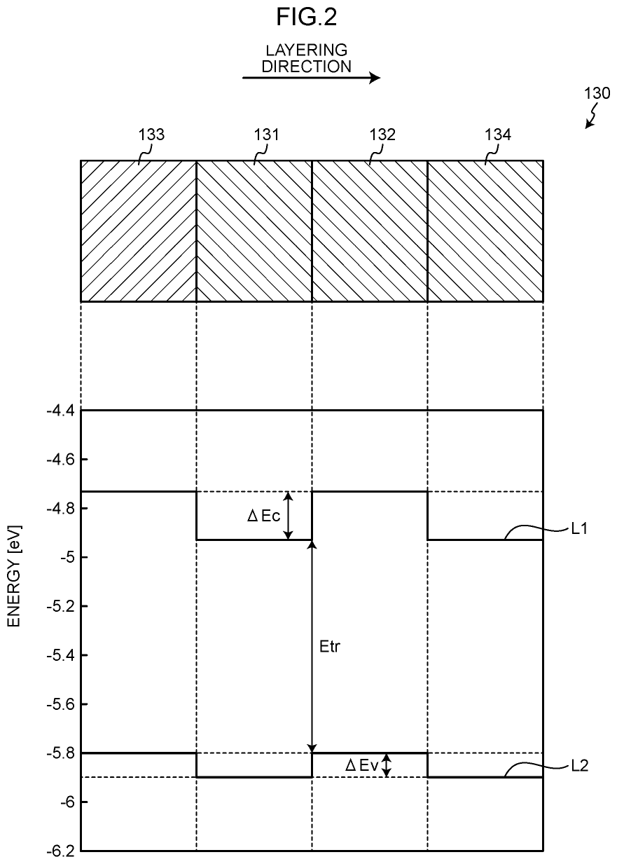

FIG. 2 is a diagram illustrating an example of the structure of the active layer illustrated in FIG. 1 and illustrating an example of the energy bands. In FIG. 2, the energy illustrated on the vertical axis represents the energy with reference to the vacuum level.

The active layer 130 has a structure in which first-type layers 132 and 133 and second-type layers 131 and 134 are alternately arranged in the layering direction. The first-type layers 132 and 133 are made of AlₓIn_{y}Ga_{(1-x-y)}AS_{z}P_{(1-z)} (where 0<x, 0<y, 0≤1-x-y, and 0<z≤1 hold true) which exhibits lattice matching with InP, that is, which has an identical lattice constant to InP constituting the substrate 121. The second-type layers 131 and 134 are made of In_{y}Ga₍₁₋ᵥ₎AS_{w}P_{(1-w)} (where 0<v≤1 and 0≤w<1 hold true) which exhibits lattice matching with InP, that is, which has an identical lattice constant to InP. In the following explanation, InᵥGa₍₁₋ᵥ₎AS_{w}P_{(1-w)} is sometimes simply referred to as AlInGaAsP. In an identical manner, InᵥGa₍₁₋ᵥ₎AS_{w}P_{(1-w)} is sometimes simply referred to as InGaAsP.

In the case in which the first-type layers 132 and 133 are made of Al_{0.21}In_{0.53}Ga_{0.26}As and the second-type layers 131 and 134 are made of In_{0.75}Ga_{0.25}AS_{0.55}P_{0.45}; a line L1 indicates the energy level of the conduction band minimum, and a line L2 indicates the energy level of the valence band maximum. As illustrated in FIG. 2, the conduction band minimum energy of the second-type layers 131 and 134 is lower than the conduction band minimum energy of the first-type layers 132 and 133; and the valence band maximum energy of the first-type layers 132 and 133 is higher than the valence band maximum energy of the second-type layers 131 and 134. As a result, the active layer 130 has a structure including the Type-II heterojunction structure based on the first-type layer 132 and the second-type layer 131. Meanwhile, the Type-II heterojunction is also called the staggered heterojunction. The first-type layer 132 constitutes a quantum well layer for electron holes, and the electron holes are confined in the first-type layer 132. The second-type layer 131 constitutes a quantum well layer for electrons, and the electrons are confined in the second-type layer 131. In the following explanation, the quantum well layer for electron holes is sometimes referred to as an electron-hole quantum well layer, and the quantum well layer for electrons is sometimes referred to as an electron quantum well layer.

The active layer 130 emits a light as a result of recombination of the electrons of the conduction band in the second-type layer 131 and the electron holes of the valence band in the first-type layer 132 that is spatially separated from the second-type layer 131, and laser oscillation occurs based on that emission of light. Herein, ΔEv represents the depth (the barrier height) of the electron-hole quantum well layer, ΔEc represents the depth (the barrier height) of the electron well layer, Eg1 represents the band gap in the first-type layer 132, and Eg2 represents the band gap in the second-type layer 131. In that case, Etr representing the energy of light emission corresponding the wavelength of laser oscillation (i.e., the wavelength of light emission) is expressed using Equation (1) given below. Herein, Etr represents the transition energy corresponding to the recombination of electrons and electron holes.

Etr=Eg1−ΔEv=Eg2−ΔEc (1)

That is, the band gap in the first-type layer 132 as well as the band gap in the second-type layer 131 is greater than the energy of light emission in the active layer 130.

In this way, when the band gap in the first-type layer 132 as well as the band gap in the second-type layer 131 is greater than the energy of light emission in the active layer 130, it can be said that a Type-II heterojunction structure is configured with the first-type layer 132 and the second-type layer 131. Meanwhile, Etr [eV] representing the energy of light emission (the linear energy) is expressed using Equation (2) given below. Herein, λ [μm] represents the wavelength of light emission.

E=1.24/λ (2)

Moreover, Eg1 and Eg2 are expressed using Equation (3) and Equation (4), respectively, given below (I. Vurgaftman, J. R. Meyer and L. R. Ram-Mohan, Journal of Applied Physics, vol. 89, No. 11, pages 5815-5875). In Equations (3) and (4), for example, “Al” represents the composition ratio of aluminum, “Eg_{AlAs}” represents the band gap of AlAs, and “B_{AlGaAs}” represents the bowing parameter of AlGaAs. Moreover, Equation (3) is the equation in the case when the composition does not contain P.

$$Eg 1 = \frac{\begin{matrix}Al * Ga * Eg ( {Al}_{( 1 - Al + Ga ) / 2} GaAs ) + Ga * In * \\ Eg ( {Ga}_{( 1 - Ga + In ) / 2} InAs ) + Al * In * Eg ( {AlIn}_{( 1 - In + Al ) / 2} As )\end{matrix}}{Al * Ga + Ga * In + Al * In} \qquad ( 3 )$$

$$where$$

$$Eg ( {Al}_{( 1 - Al + Ga ) / 2} GaAs ) = \frac{1 - Al + Ga}{2} * {Eg}_{AlAs} + \frac{1 - Ga + Al}{2} * {Eg}_{GaAs} - \frac{1 - Al + Ga}{2} * \frac{1 - Ga + Al}{2} * {B}_{AlGaAs}$$

$$Eg ( {Ga}_{( 1 - Ga + In ) / 2} In As ) = \frac{1 - Ga + In}{2} * {Eg}_{GaAs} + \frac{1 - In + Ga}{2} * {Eg}_{InAs} - \frac{1 - Ga + In}{2} * \frac{1 - In + Ga}{2} * {B}_{InGaAs}$$

$$Eg ( {AlIn}_{( 1 - In + Al ) / 2} As ) = \frac{1 - Al + In}{2} * {Eg}_{AlAs} + \frac{1 - In + Al}{2} * {Eg}_{InAs} - \frac{1 - Al + In}{2} * \frac{1 - In + Al}{2} * {B}_{AlInAs}$$

$$Eg 2 = \frac{\frac{In * Ga * As * {Eg}_{InGaAs} + In * Ga * P * {Eg}_{InGaP} +}{Ga * As * P * {Eg}_{GaAsP} + In * As * P * {Eg}_{InAsP}}}{In * Ga + As * P} \qquad ( 4 )$$

$$where$$

$${Eg}_{InGaAs} = In * {Eg}_{InAs} + Ga * {Eg}_{GaAs} - In * Ga * {B}_{InGaAs}$$

$${Eg}_{InGaP} = In * {Eg}_{InP} + Ga * {Eg}_{GaP} - In * Ga * {B}_{InGaP}$$

$${Eg}_{GaAsP} = As * {Eg}_{GaAs} + P * {Eg}_{GaP} - As * P * {B}_{GaAsP}$$

$${Eg}_{InAsP} = As * {Eg}_{InAs} + P * {Eg}_{InP} - As * P * {B}_{InAsP}$$

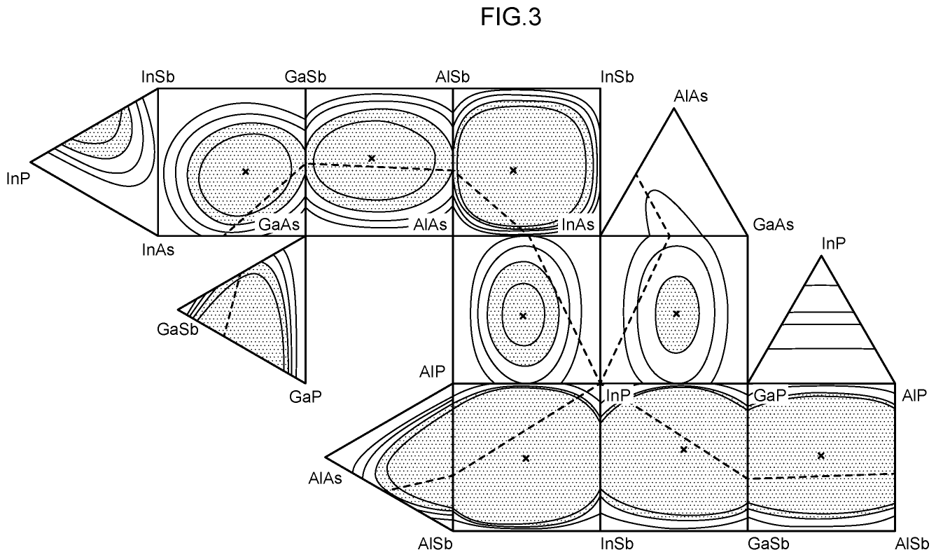

FIG. 3 is a diagram illustrating the spinodal curve of a ternary semiconductor alloy or a quaternary semiconductor alloy (Kentaro ONABE, Japanese Journal of Applied Physics, Volume 53 Issue 9, 1984, pages 802-808). A ternary semiconductor alloy or a quaternary semiconductor alloy is a semiconductor alloy containing Al, In, Ga, As, P, or Sb. In FIG. 3, the curved lines represent the spinodal lines that are the boundaries between the metastable regions and the unstable regions at a predetermined temperature. The inner sides of the curved lines represent the composition unstable regions. A thick dashed line represents the composition that exhibits lattice matching with InP. The dotted regions indicate the inside regions of the spinodal regions at 800° C. as an example. From the extent of overlapping between the thick dashed line and the dotted regions, the composition of an alloy that contains Sb and that exhibits lattice matching with InP is often present in the composition unstable regions. In contrast, in the case of an alloy such as InGaAsP, AlInAsP, or AlInGaAs that exhibits lattice matching with InP, the portions in which the thick dashed line overlaps with the dotted regions are few in number. Hence, when the active layer has the first-type layers and the second-type layers made of such an alloy, the issue of having difficulty in achieving crystal growth due to composition non-miscibility or phase separation can be resolved, and manufacturability can be improved.

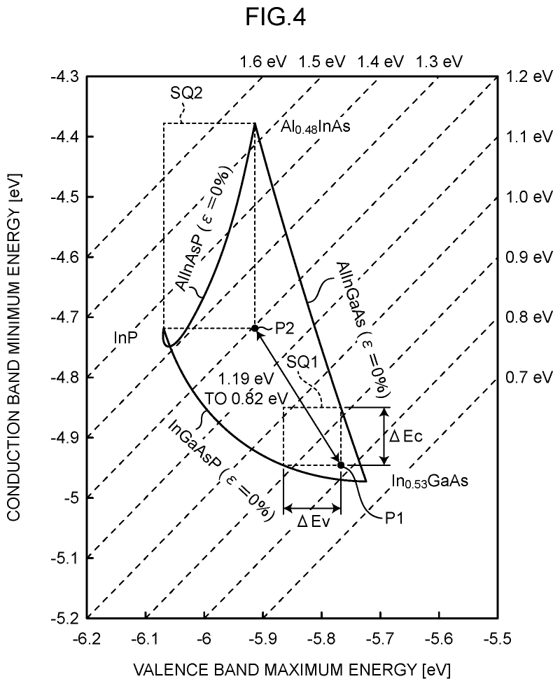

Given below is the explanation about an example of selecting the composition ratio of the alloy in the first-type layer 132 and the second-type layer 131. FIG. 4 is a diagram illustrating the relationship between the conduction band minimum energy and the valence band maximum energy of the alloys that exhibit lattice matching with InP. In FIG. 4, the solid lines indicate the path of the coordinate points that are represented by combinations of the conduction band minimum energy and the valence band maximum energy in the case of varying the composition ratio of InGaAsP, AlInAsP, and AlInGaAs which exhibit lattice matching with InP. Meanwhile, “ε=0%” implies that there is no lattice strain. Moreover, the energy difference between the valence band maximum energy and the conduction band minimum energy represents the band gap, and the oblique dashed lines represent the energy lines of the band gap (from 0.7 eV to 1.6 eV).

In order to configure a Type-II heterojunction structure based on the first-type layer 132 and the second-type layer 131, the first-type layer 132 constituting the electron-hole well layer needs to have a higher conduction band energy and a higher valence band energy than the conduction band energy and the valence band energy of the second-type layer 131 constituting the electron well layer. Hence, in FIG. 4, as the alloy constituting the first-type layer 132, an alloy is selected that is positioned to the upper right of the alloy of the second-type layer 131. That is, AlInGaAs can be selected as the alloy for the first-type layer 132, and InGaAsP can be selected as the alloy for the second-type layer 131.

For example, as the composition of the alloys, a single point on the solid line representing InGaAsP and a single point on the solid line representing AlInGaAs are selected, and a rectangle SQ1 is formed with those points as the vertices. In that case, of the rectangle SQ1, the length of the sides parallel to the horizontal axis represents ΔEv, the length of the sides parallel to the vertical axis represents ΔEc, and the band gap at a point P1 equivalent to the bottom right vertex of the rectangle SQ1 represents the transition energy.

As the composition of the alloys, when a single point on the solid line representing InGaAsP and a single point on the solid line representing AlInGaAs are selected, the transition energy Etr is at the lowest when expressed using the point P1 of the rectangle SQ1 and is at the highest when expressed using a point P2 of the rectangle SQ2. Herein, it is assumed that at least 100 meV of ΔEc or ΔEv is required for the confinement of the electrons or the electron holes.

As can be understood from the equipotential line of the band gap, the transition energy Etr corresponding to the point P1 is approximately equal to 0.82 eV and the transition energy Etr corresponding to the point P2 is approximately equal to 1.19 eV. Hence, depending on the selection of the composition of the alloy, the semiconductor light-emitting device 100 becomes able to output a laser light having an extremely wide wavelength range usable in optical communication, such as from about 1040 nm, which is equivalent to about 1.19 eV, to about 1510 nm, which is equivalent to about 0.82 eV. Particularly, on account of including the 0 band (for example, from 1260 nm to 1360 nm) which represents an important wavelength band as far as optical communication is concerned, the abovementioned wavelength range is suitable for practical use.

For example, the following explanation is given about the case in which the first-type layer 132 is made of Al_{0.21}In_{0.53}Ga_{0.26}As and the second-type layer 131 is made of In_{0.75}Ga_{0.25}AS_{0.55}P_{0.45}. In that case, the band gap of the first-type layer 132 is approximately equal to 1.05 eV, and the band gap of the second-type layer 131 is approximately equal to 0.95 eV. Moreover, ΔEc is approximately equal to 0.20 eV, and ΔEv is approximately equal to 0.10 eV. As a result, the transition energy is approximately equal to 0.85 eV, and is approximately equal to 1457 nm in terms of the wavelength of the light.

Moreover, as a result of appropriately selecting the composition of the alloy, without having to vary the strain of the alloy, not only the transition energy (the emission wavelength) can be set to have a high degree of freedom, but the ratio between ΔEc and ΔEv can also be set to have a high degree of freedom. Since the adjustments of such ratios is effective in reducing the Auger recombination, the configuration of the active layer 130 becomes useful also in achieving reduction in the Auger recombination. Hence, the semiconductor light-emitting device 100 is useful also from the perspective of achieving high-temperature performance.

As explained above, the semiconductor light-emitting device 100 has excellent high-temperature performance and has excellent manufacturability.

### Second Embodiment

A semiconductor light-emitting device according to a second embodiment is configured by substituting an active layer 130A for the active layer 130 of the semiconductor light-emitting device 100 according to the first embodiment. Accordingly, the following explanation is given about the structure and the characteristics of the active layer 130A, and the remaining configuration is not explained again.

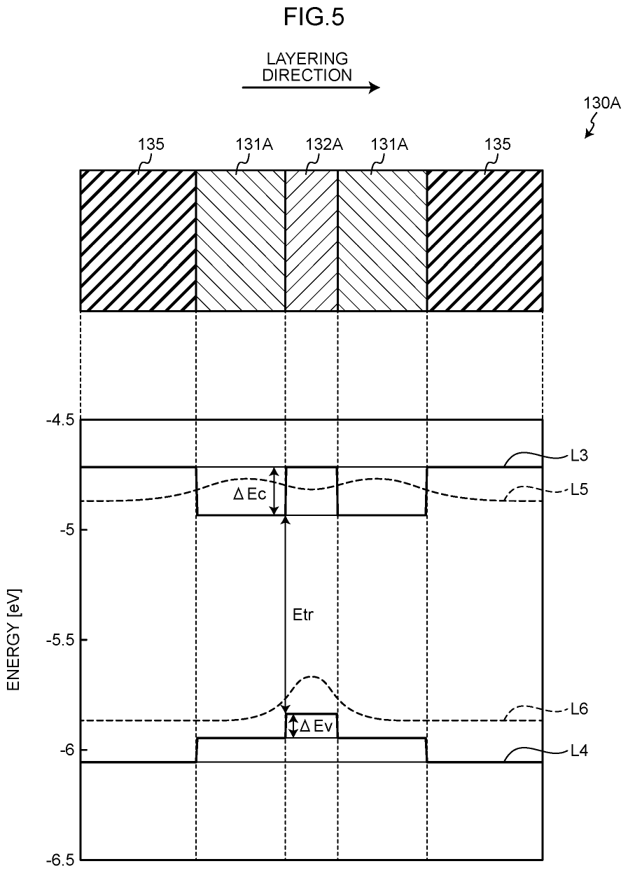

FIG. 5 is a diagram illustrating an example of the structure of the active layer and illustrating an example of the energy bands in the semiconductor light-emitting device according to the second embodiment. The active layer 130A has a multiple quantum well structure in which a barrier layer 135, a second-type layer 131A, a first-type layer 132A, the second-type layer 131A, and the barrier layer 135 are layered in that order in the layering direction.

In an identical manner to the first-type layer 132 in the semiconductor light-emitting device 100, the first-type layer 132A is made of AlₓIn_{y}Ga_{(1-x-y)}AS_{z}P_{(1-z)} (where 0<x, 0<y, 0≤1-x-y, and 0<z≤1 hold true). In an identical manner to the second-type layer 131 in the semiconductor light-emitting device 100, the second-type layer 131A is made of InᵥGa₍₁₋ᵥ₎AS_{w}P_{(1-w)} (where 0<v≤1 and 0≤w<1 hold true). The active layer 130A includes two Type-II heterojunction structures.

The pair of barrier layers 135 are made of AlᵣInₛGa₍₁₋ᵣ₋ₛ₎ASₜP₍₁₋ₜ₎ (where 0<r, 0<s, 0≤1-r-s, and 0≤t<1 hold true) that has the conduction band minimum energy to be higher than the conduction band minimum energy of the first-type layer 132A and that has the valence band maximum energy to be lower than the valence band maximum energy of the second-type layer 131A. The pair of barrier layers 135 sandwich the two Type-II heterojunction structures. The barrier layers 135 are made of, for example, InP. Meanwhile, the barrier layers 135 can be made of AlInGaAsP having a lower Ga composition ratio (i.e., 1-r-s) than the Ga composition ratio in the first-type layer 132A.

In the case in which the first-type layer 132 is made of Al_{0.21}In_{0.53}Ga_{0.26}As, the second-type layer 131A is made of In_{0.75}Ga_{0.25}AS_{0.55}P_{0.45}, the barrier layers 135 are made of InP, the first-type layer 132A has the film thickness of 3 nm, and the second-type layer 131A has the film thickness of 5 nm; a line L3 indicates the energy level of the conduction band minimum, and a line L4 indicates the energy level of the valence band maximum. Moreover, a line L5 indicates the wave function for electrons, and a line L6 indicates the wave function for electron holes. As illustrated in FIG. 5, as a result of having two second-type layers 131A, there is concatenation of two wave functions for electrons. With that, there is an increase in the overlapping between the wave functions for electrons and the wave function for electron holes, and hence the probability of recombination increases. When the first-type layer 132A, the second-type layer 131A, and the barrier layers 135 are made of the alloys as explained earlier; an energy E1 based on the quantum effect of the conduction band is approximately equal to 0.07 eV; an energy H1 based on the quantum effect of the valence band is approximately equal to 0.03 eV; and the transition energy Etr+E1+H1 after taking into account the quantum effect is approximately equal to 0.949 eV, and is approximately equal to 1307 nm in terms of the wavelength of the light.

In an identical manner to the semiconductor light-emitting device 100 according to the first embodiment, the semiconductor light-emitting device according to the second embodiment as configured in the manner explained above has excellent high-temperature performance and has excellent manufacturability.

Moreover, in the semiconductor light-emitting device according to the second embodiment, since there is a higher probability of recombination between electrons and electron holes, there is enhancement in the light emission efficiency.

### Third Embodiment

A semiconductor light-emitting device according to a third embodiment is configured by substituting an active layer 130B for the active layer 130 of the semiconductor light-emitting device 100 according to the first embodiment. Accordingly, the following explanation is given about the structure and the characteristics of the active layer 130B, and the remaining configuration is not explained again.

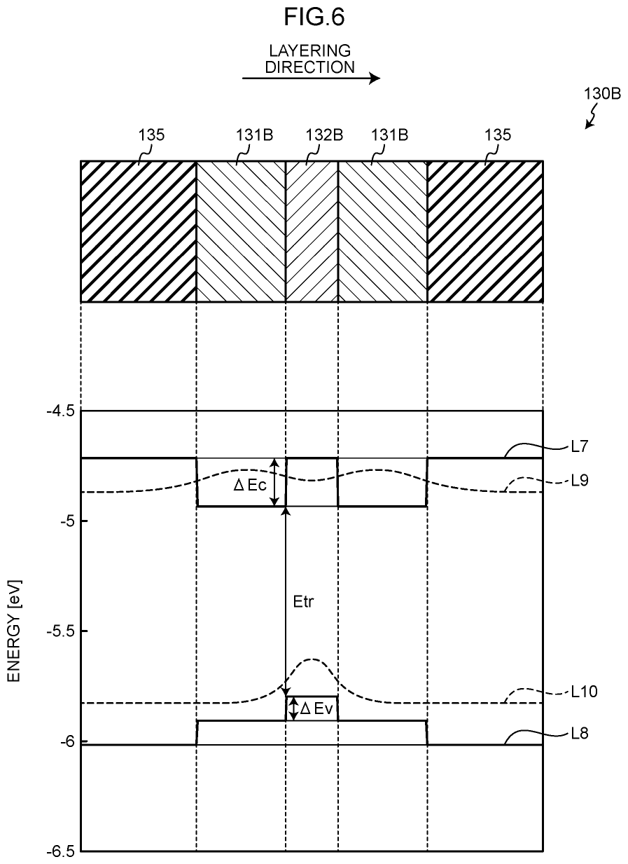

FIG. 6 is a diagram illustrating an example of the structure of the active layer and illustrating an example of the energy bands in the semiconductor light-emitting device according to the third embodiment. The active layer 130B has a multiple quantum well structure in which the barrier layer 135, a second-type layer 131B, a first-type layer 132B, the second-type layer 131B, and the barrier layer 135 are layered in that order in the layering direction.

In an identical manner to the first-type layer 132 in the semiconductor light-emitting device 100, the first-type layer 132B is made of AlₓIn_{y}Ga_{(1-x-y)}AS_{z}P_{(1-z)}. However, the first-type layer 132B differs from the first-type layer 132 in the way of having a higher lattice constant than the lattice constant of InP and having the compressive strain of 1.0% with respect to InP. Moreover, in an identical manner to the second-type layer 131 in the semiconductor light-emitting device 100, the second-type layer 131A is made of InᵥGa₍₁₋ᵥ₎AS_{w}P_{(1-w)}. However, the second-type layer 131B differs from the second-type layer 131 in the way of having a lower lattice constant than the lattice constant of InP and having the tensile strain of 0.3% with respect to InP. The active layer 130B includes two Type-II heterojunction structures.

The pair of barrier layers 135 are identical to the pair of barrier layers 135 according to the second embodiment. Hence, that explanation is not given again.

In the active layer 130B; the layering structure of the second-type layer 131B, the first-type layer 132B, and the second-type layer 131B has the thickness-weighted average strain to be lower than 2%. A thickness-weighted average strain εₐᵥₑ is expressed using Equation (5) given below. Herein, ε represents the strain [%] in the layers, and w represents the film thickness [nm].

εₐᵥₑ=(Σεw/Σw) (5)

Thus, for example, when the first-type layer 132B has the film thickness of 3 nm and the second-type layer 131B has the film thickness of 5 nm,

εₐᵥₑ=((1[%])×(3[m])+((−0.3%))×((5[m])×2))/Σ((3 [nm])+(5[nm])×2)=0%
holds true. As a result, the thickness-weighted average strain becomes lower than 2%.

With reference to FIG. 6, in the case in which the first-type layer 132B is made of Al_{0.25}In_{0.67}Ga_{0.08}As composed to have the compressive strain of 1.0% with respect to InP, the second-type layers 131B are made of In_{0.70}Ga_{0.30}AS_{0.56}P_{0.44} composed to have the tensile strain of 0.3% with respect to InP, the barrier layers 135 are made of Al_{0.25}In_{0.75}AS_{0.53}P_{0.47} composed to exhibit lattice matching with InP, the first-type layer 132B has the film thickness of 3 nm, and the second-type layer 131B has the film thickness of 5 nm; a line L7 indicates the energy level of the conduction band minimum, and a line L8 indicates the energy level of the valence band maximum. Herein, Al_{0.25}In_{0.67}Ga_{0.08}As has the lattice constant of 5.9275 angstrom, and hence represents the compressive strain of 1.0% with respect to InP that has the lattice constant of 5.8688 angstrom. Moreover, In_{0.70}Ga_{0.30}AS_{0.56}P_{0.44} has the lattice constant of 5.8512 angstrom, and hence represents the tensile strain of 0.3% with respect to InP. Meanwhile, a line L9 indicates the wave function for electrons, and a line L10 indicates the wave function for electron holes. As illustrated in FIG. 6, as a result of having two second-type layers 131B, there is concatenation of two wave functions for electrons. Hence, in an identical manner to the second embodiment, there is an increase in the overlapping between the wave functions for electrons and the wave function for electron holes, and hence the probability of recombination increases.

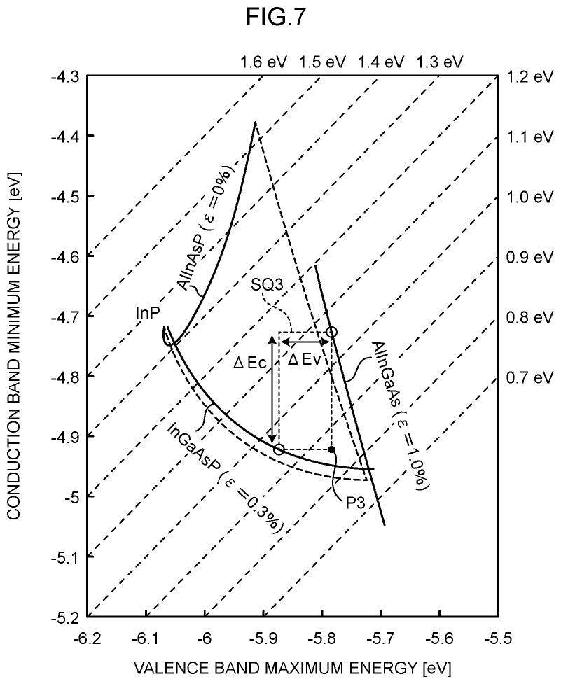

FIG. 7 is a diagram illustrating the relationship between the conduction band minimum energy and the valence band maximum energy of the active layer 130B according to the third embodiment. When the first-type layer 132B, the second-type layers 131B, and the barrier layers 135 are made of alloys as explained earlier; a single point on the solid line representing InGaAsP and a single point on the solid line representing AlInGaAs are selected as the composition of the alloys, and a rectangle SQ3 is formed with those points as the vertices. In that case, of the rectangle SQ3, the band gap at a point P3, which represents the bottom right vertex of the rectangle SQ3, indicates the transition energy Etr. The transition energy Etr is approximately equal to 0.845 eV when the quantum effect is not taken into account; the energy E1 based on the quantum effect of the conduction band is approximately equal to 0.07 eV; and the energy H1 based on the quantum effect of the valence band is approximately equal to 0.03 eV. After taking the quantum effect into account, the transition energy Etr+E1+H1 is approximately equal to 0.945 V, and is approximately equal to 1311 nm in terms of the wavelength of the light.

In an identical manner to the semiconductor light-emitting devices according to the first and second embodiments, the semiconductor light-emitting device according to the third embodiment as configured in the manner explained above has excellent high-temperature performance and has excellent manufacturability.

Moreover, in an identical manner to the semiconductor light-emitting device according to the second embodiment, in the semiconductor light-emitting device according to the third embodiment too, there is enhancement in the light emission efficiency.

Furthermore, in the semiconductor light-emitting device according to the third embodiment, since the first-type layer 132B that constitutes the electron-hole well layer has a compressive strain, a barrier height ΔEc of the electron well layer can be increased in relative terms. Hence, in addition to achieving the effect based on the typical strain such as separation of heavily-doped electron-hole bands and lightly-doped electron-hole bands or effective mass reduction, it is also possible to achieve the effect of reducing carrier leakage. Furthermore, an effect of reducing the threshold current.

Moreover, in the semiconductor light-emitting device according to the third embodiment, the second-type layers 131B that have the tensile strain compensate for the compressive strain of the first-type layer 132B, so that the thickness-weighted average strain becomes lower than about 28. As a result, in a multiple quantum well structure, the strain can be compensated without having to sandwich barrier layers in between the first-type layer and the second-type layers. That characteristic is useful in the case of, for example, increasing the optical confinement factor in a short-cavity laser device such as a surface-emitting laser device.

### Fourth Embodiment

A semiconductor light-emitting device according to a third embodiment is configured by substituting an active layer 130C for the active layer 130 of the semiconductor light-emitting device 100 according to the first embodiment. Accordingly, the following explanation is given about the structure and the characteristics of the active layer 130C, and the remaining configuration is not explained again.

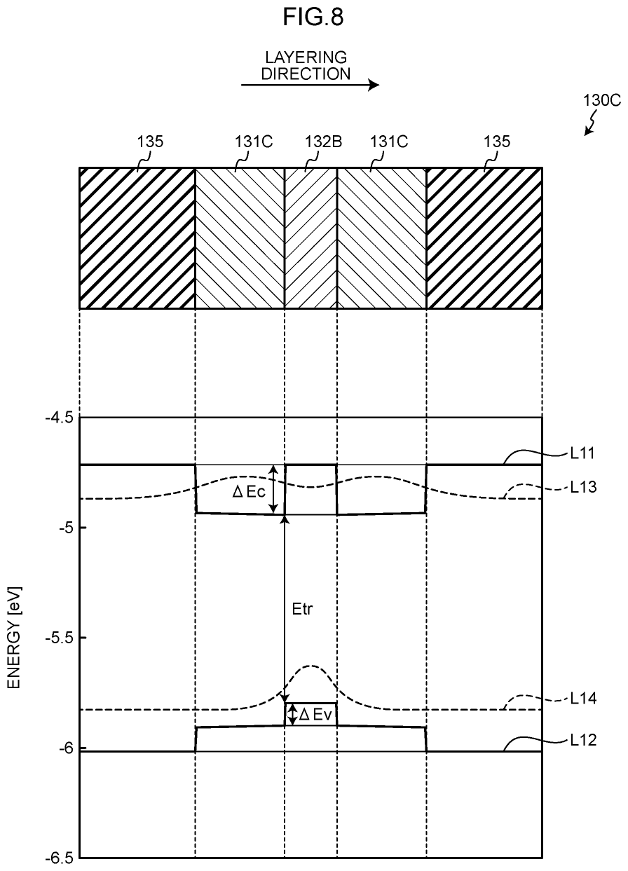

FIG. 8 is a diagram illustrating an example of the structure of the active layer and illustrating an example of the energy bands in the semiconductor light-emitting device according to the fourth embodiment. The active layer 130C has a multiple quantum well structure in which the barrier layer 135, a second-type layer 131C, the first-type layer 132B, the second-type layer 131C, and the barrier layer 135 are layered in that order in the layering direction.

The first-type layer 132B and the pair of barrier layers 135 are identical to the first-type layer 132B and the pair of barrier layers 135, respectively, according to the third embodiment. Hence, that explanation is not given again.

In an identical manner to the second-type layers 131B according to the third embodiment, the second-type layers 131C are made of InᵥGa₍₁₋ᵥ₎AS_{w}P_{(1-w)} composed to have the tensile strain of 0.3% with respect to InP. However, the second-type layers 131C differ from the second-type layers 131B in the way of having such variation in the composition that the conduction band minimum energy decreases toward the first-type layer 132B in the layer thickness direction. More particularly, toward the first-type layer 132B in the layer thickness direction, the composition of the second-type layers 131B changes from In_{0.70}Ga_{0.30}AS_{0.56}P_{0.44} to In_{0.68}Ga_{0.32}AS_{0.60}P_{0.40} while having the tensile strain maintained at 0.3%. Such variation is also called graded composition. Such variation either may be continuous or stepwise.

With reference to FIG. 8, a line L11 indicates the energy level of the conduction band minimum, and a line L12 indicates the energy label of the valence band maximum. Moreover, a line L13 indicates the wave function for electrons, and a line L14 indicates the wave function for electron holes. In that case, the energy E1 based on the quantum effect of the conduction band is approximately equal to 0.07 eV; the energy H1 based on the quantum effect of the valence band is approximately equal to 0.03 eV; and the transition energy Etr+E1+H1 after taking into account the quantum effect is approximately equal to 0.940 eV, and is approximately equal to 1318 nm in terms of the wavelength of the light.

The semiconductor light-emitting device according to the fourth embodiment as configured in the manner explained above enables achieving identical effects to the effects achieved in the semiconductor light-emitting device according to the third embodiment. Moreover, in the semiconductor light-emitting device according to the fourth embodiment, the composition of the second-type layer 131C varies in such a way that the conduction band minimum energy decreases toward the first-type layer 132B in the layer thickness direction. As a result, the concatenation between the two wave functions for electrons of the two second-type layers 131C becomes stronger. With that, there is further increase in the overlapping between the wave functions for electrons and the wave function for electron holes, and hence the probability of recombination increases. For example, in comparison to the third embodiment, according to the fourth embodiment, as an example, the overlapping between the wave functions for electrons and the wave function for electron holes sometimes increases from 48.9% to 50.5%.

### Fifth Embodiment

A semiconductor light-emitting device according to a fifth embodiment is configured by substituting an active layer 130D for the active layer 130 of the semiconductor light-emitting device 100 according to the first embodiment. Accordingly, the following explanation is given about the structure and the characteristics of the active layer 130D, and the remaining configuration is not explained again.

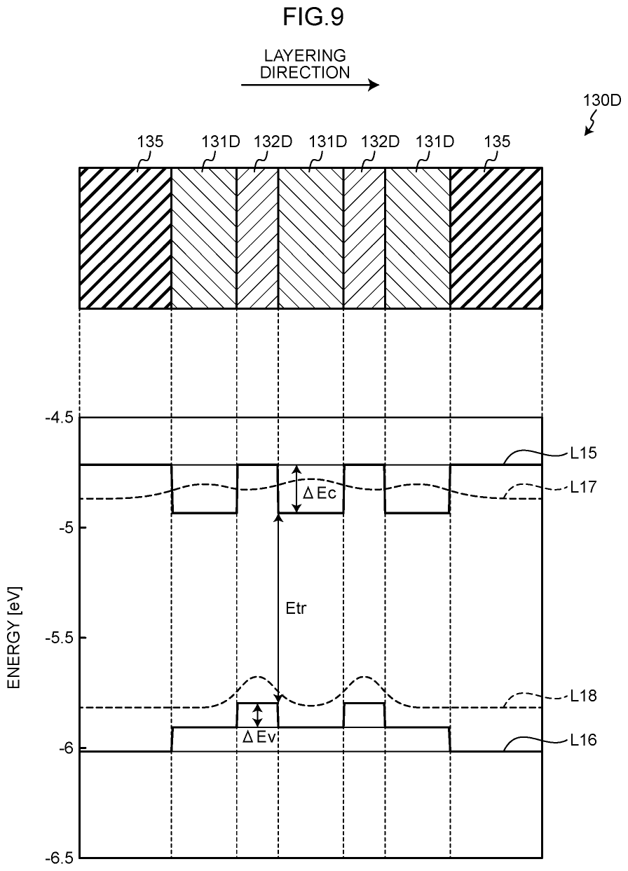

FIG. 9 is a diagram illustrating an example of the structure of the active layer and illustrating an example of the energy bands in the semiconductor light-emitting device according to the fifth embodiment. The active layer 130D has a multiple quantum well structure in which the barrier layer 135, a second-type layer 131D, a first-type layer 132D, the second-type layer 131D, the first-type layer 132D, the second-type layer 131D, and the barrier layer 135 are layered in that order in the layering direction.

The first-type layers 132D are made of, for example, Al_{0.25}In_{0.67}Ga_{0.08}As composed to have the compressive strain of 1.0% with respect to InP. The second-type layers 131D are made of In_{0.70}Ga_{0.30}AS_{0.56}P_{0.44} composed to have the tensile strain of 0.3% with respect to InP. The first-type layers 132D have the film thickness of 3 nm, and the second-type layers 131D have the film thickness of 5 nm. The barrier layers 135 are made of, for example, Al_{0.25}In_{0.54}AS_{0.53}P_{0.47} composed to exhibit lattice matching with InP. The active layer 130D includes four Type-II heterojunction structures.

In the case of having the abovementioned composition ratio, a line L15 indicates the energy level of the conduction band minimum, and a line L16 indicates the energy label of the valence band maximum. Moreover, a line L17 indicates the wave function for electrons, and a line L18 indicates the wave function for electron holes.

The semiconductor light-emitting device according to the fifth embodiment as configured in the manner explained above enables achieving identical effects to the effects achieved in the semiconductor light-emitting device according to the third embodiment. Moreover, in the semiconductor light-emitting device according to the fifth embodiment, there are three second-type layers 131D constituting an electron well layer, and there are two first-type layers 132D constituting an electron-hole well layer. Thus, there occurs concatenation among the wave functions for electrons and there occurs concatenation between the wave functions for electron holes. Hence, the overlapping between the wave functions for electrons and the wave functions for electron holes can be increased further. Moreover, since the strain gets compensated among the first-type layers 132D and the second-type layers 131D, the thickness-weighted average strain can be reduced to about 0.07% regardless of having a multiple quantum well structure. Meanwhile, in the composition explained above, the energy E1 based on the quantum effect of the conduction band is approximately equal to 0.06 eV, and the energy H1 based on the quantum effect of the valence band is approximately equal to 0.03 eV. The transition energy Etr+E1+H1 after taking into account the quantum effect is approximately equal to 0.942 eV, and is approximately equal to 1316 nm in terms of the wavelength of the light. Moreover, in comparison to the third embodiment, according to the fifth embodiment, as an example, the overlapping between the wave functions for electrons and the wave functions for electron holes sometimes increases from 48.9% to 56.8%.

### Sixth Embodiment

A semiconductor light-emitting device according to a fifth embodiment is configured by substituting an active layer 130E for the active layer 130 of the semiconductor light-emitting device 100 according to the first embodiment. Accordingly, the following explanation is given about the structure and the characteristics of the active layer 130E, and the remaining configuration is not explained again.

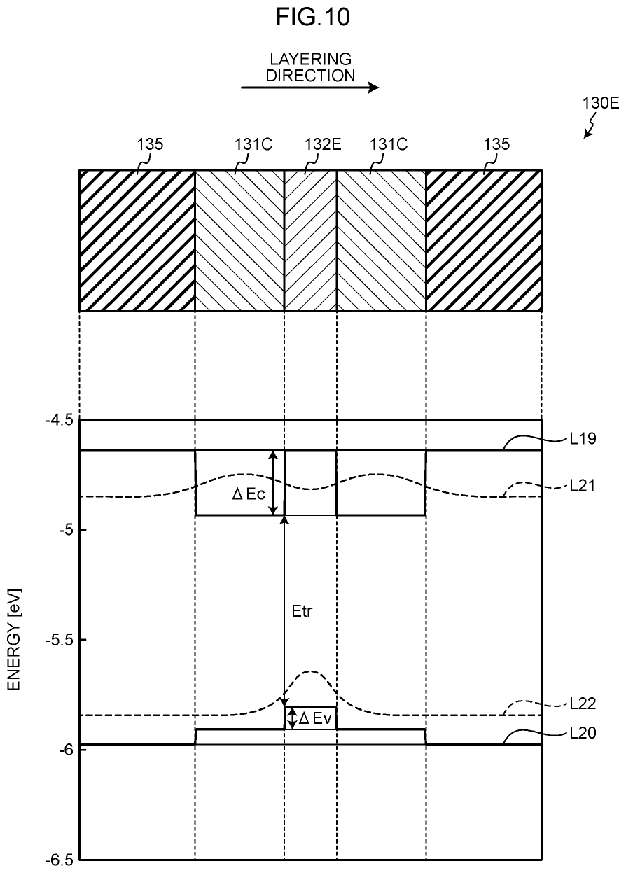

FIG. 10 is a diagram illustrating an example of the structure of the active layer and illustrating an example of the energy bands in the semiconductor light-emitting device according to the sixth embodiment. The active layer 130E has a multiple quantum well structure in which the barrier layer 135, the second-type layer 131C, a first-type layer 132E, the second-type layer 131C, and the barrier layer 135 are layered in that order in the layering direction.

In an identical manner to the first-type layer 132B according to the third embodiment, the first-type layer 132E is composed to have the compressive strain of 1.0% with respect to InP, but is made of AlₓIn_{y}As that is a ternary alloy. Herein, AlₓIn_{y}As is, for example, Al_{0.33}In_{0.67}As. Moreover, in an identical manner to the second-type layers 131B in the semiconductor light-emitting device according to the third embodiment, the second-type layers 131B are made of InᵥGa₍₁₋ᵥ₎AS_{w}P_{(1-w)} composed to have the tensile strain of 0.3% with respect to InP. The barrier layers 135 are made of Al_{0.33}In_{0.67}AS_{0.70}P_{0.30} composed to exhibit lattice matching with InP.

When the first-type layer 132E, the second-type layers 131E, and the barrier layers 135 are made of the alloys as explained earlier; a line L19 indicates the energy level of the conduction band minimum, and a line L20 indicates the energy level of the valence band maximum. Moreover, a line L21 indicates the wave function for electrons, and a line L22 indicates the wave function for electron holes.

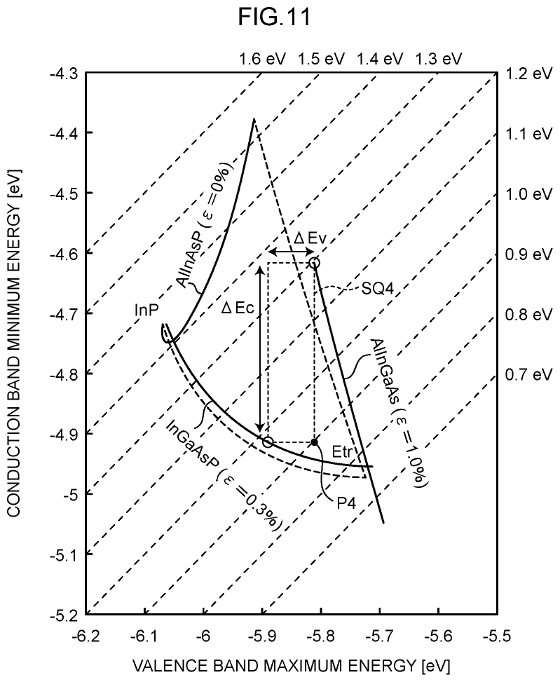

FIG. 11 is a diagram illustrating the relationship between the conduction band minimum energy and the valence band maximum energy of the active layer 130E according to the sixth embodiment. When the first-type layer 132E, the second-type layers 131E, and the barrier layers 135 are made of the alloys as explained earlier; a rectangle SQ4 is formed in which a single point on the solid line representing InGaAsP is a vertex, and a single point equivalent to Al_{0.33}In_{0.67}As on the solid line representing AlInGaAs is a vertex. In that case, the band gap at a point P4 equivalent to the bottom right vertex of the rectangle SQ4 represents the transition energy Etr. The transition energy Etr is approximately equal to 0.987 eV, and is approximately equal to 1256 nm in terms of the wavelength of the light.

The semiconductor light-emitting device according to the sixth embodiment as configured in the manner explained above enables achieving identical effects to the effects achieved in the semiconductor light-emitting device according to the third embodiment. Moreover, in the semiconductor light-emitting device according to the sixth embodiment, since the first-type layer 132B has a ternary configuration, crystal growth can be achieved more easily and more excellent manufacturability can also be achieved.

### Seventh Embodiment

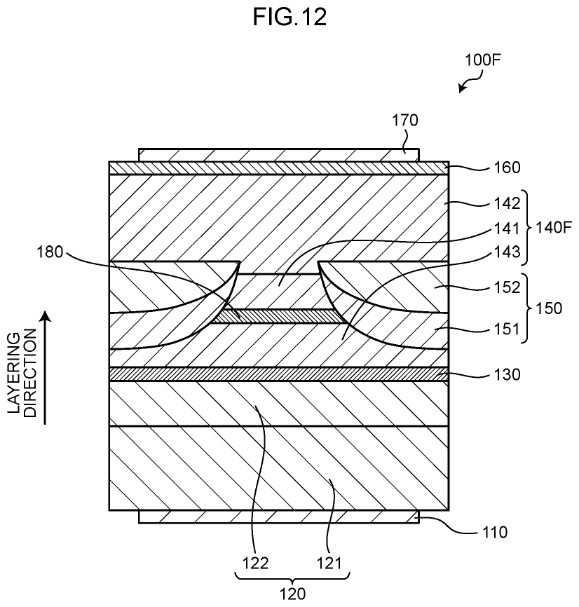

FIG. 12 is a schematic cross-sectional view of a semiconductor light-emitting device according to a seventh embodiment. A semiconductor light-emitting device 100F is configured as a semiconductor laser device. The semiconductor light-emitting device 100F includes the n-type semiconductor portion 120 having the n-side electrode 110 formed on the reverse side thereof; the active layer 130; a p-type semiconductor portion 140F; the current blocking layer 150; the contact layer 160; the p-side electrode 170; and a guiding layer 180. The semiconductor light-emitting device 100F outputs a laser light from the active layer 130 in the perpendicular direction to the plane of FIG. 12.

The n-type semiconductor portion 120 has an identical configuration to the corresponding constituent element of the semiconductor light-emitting device 100 illustrated in FIG. 1, and includes the substrate 121 and the n-type cladding layer 122.

With the layering direction facing upward; the active layer 130, a semiconductor layer 143, the guiding layer 180, semiconductor layers 141 and 142, the contact layer 160, and the p-side electrode 170 are sequentially placed on the n-type cladding layer 122 of the n-type semiconductor portion 120.

The active layer 130 has an identical configuration to the corresponding constituent element of the semiconductor light-emitting device 100.

The semiconductor layer 143 is made of p-InP, and constitutes the p-type semiconductor portion 140F along with the semiconductor layers 141 and 142. The semiconductor layers 141 and 142 have identical configuration to the corresponding constituent element of the semiconductor light-emitting device 100.

The guiding layer 180 has a higher refractive index than the refractive index of InP and is made of, for example, InGaAsP. The guiding layer 180 may exhibit lattice matching with InP.

The guiding layer 180 and some part of the p-type semiconductor portion 140F have the stripe mesa structure. Since the guiding layer 180 has the stripe shape, the light emitted by the active layer 130 gets confined in the left and right directions with reference to FIG. 12 due to the guiding layer 180. In the stripe mesa structure, the width suitable for guiding the light, which is emitted from the active layer 130, in the single mode (for example, the width of 2 μm) is provided by performing etching. Both sides of the stripe mesa structure (i.e., the left and right directions with reference to FIG. 12) are buried with the current blocking layer 150 that is formed by layering the current blocking layer 151 and the current blocking layer 152. Moreover, the semiconductor layer 142 is formed to cover the semiconductor layer 141 and the current blocking layer 150. The current blocking layer 150 has an identical configuration to the corresponding constituent element of the semiconductor light-emitting device 100.

The n-side electrode 110, the contact layer 160, and the p-side electrode 170 have identical configurations to the corresponding constituent elements of the semiconductor light-emitting device 100.

In the semiconductor light-emitting device 100F, an HR film and an AR film are formed in an identical manner to the semiconductor light-emitting device 100. In the semiconductor light-emitting device 100F, when an electric current is injected from the p-side electrode 170, a laser light is output mainly from the end face having the AR film formed thereon.

The semiconductor light-emitting device 100F configured in the manner explained above enables achieving identical effects to the effects achieved in the semiconductor light-emitting device according to the first embodiment. Moreover, in the semiconductor light-emitting device 100F, even when a stripe mesa structure is formed by performing etching, since the active layer 130 does not get exposed, the layers containing Al are at no risk of oxidation on account of coming into contact with the air.

The active layer 130 in the semiconductor light-emitting device 100F may be replaced with one of the active layers 130A to 130E according to the second to sixth embodiments described above.

In the embodiments of the present disclosure, when the quantum well structure for electrons is configured with barrier layers, second-type layers (electron well layers), and a first-type layer (an electron-hole well layer), if the conduction band minimum energy of the barrier layers is lower than the conduction band minimum of the electron-hole well layer, the effect of barrier height based on the electron-hole well layer cannot be achieved. Moreover, if the valence band maximum energy of the barrier layers is higher than the valence band maximum of the electron well layers, the Type-II heterojunction occurs between the barrier layers and the electron well layers, and different recombination occurs than the desired transition energy. The same is the case when the quantum well structure for the electron holes is configured with barrier layers, an electron-hole well layer, and electron well layers. In the case of a Type-II heterojunction structure that concatenates two wave functions for electrons in order to increase the overlapping between the wave functions for electrons and the wave function for electron holes, the overlapping among the wave functions can be increased by increasing the conduction band minimum energy of the barrier layers. In that case, AlInAsP is suitable for use in the barrier layers.

In the example of the composition ratio of the first-type layers according to the embodiments described above, the first-type layers are made of AlₓIn_{y}Ga_{(1-x-y)}As that does not contain P. Alternatively, the first-type layers may be made of AlₓIn_{y}Ga_{(1-x-y)}AS_{z}P_{(1-z)} that contains P. However, when the first-type layers are made of AlₓIn_{y}Ga_{(1-x-y})As that does not contain P, it is easier to increase the barrier heights ΔEc and ΔEv.

In the semiconductor light-emitting devices according to the third to sixth embodiments described above, the first-type layer constituting the electron-hole well layer has the compressive strain, and the second-type layers constituting the electron well layers have the tensile strain and compensate the compressive strain of the first-type layer. When the thickness-weighted average strain is lower than about 2% due to the first-type layer, the second-type layers may be made of a semiconductor alloy composed to exhibit lattice matching with InP.

Meanwhile, in the active layer according to the fifth embodiment described above, although there are three second-type layers constituting the electron well layer, there is no particular restriction on the number of second-type layers. Thus, there can be four or more second-type layers. Moreover, there is also no particular restriction on the number of first-type layers constituting the electron-hole well layer. Thus, there may be three or more first-type layers. Furthermore, either the number of first-type layers may be greater than the second-type layers, or vice versa.

In the embodiments described above, the semiconductor light-emitting device is configured as a semiconductor laser device. Alternatively, the semiconductor light-emitting device may be configured as a semiconductor optical amplifier. When configured as a semiconductor optical amplifier, the semiconductor light-emitting device is configured to not include a laser cavity. Alternatively, when configured as a distributed feed-back (DFB) laser device, the semiconductor light-emitting device has a diffraction grating layer formed close to the active layer. Still alternatively, when configured as a surface-emitting laser device, the semiconductor light-emitting device has the active layer placed inside a vertical cavity surface emitting laser.

According to the present disclosure, it is possible to achieve a semiconductor light-emitting device having excellent high-temperature performance and having excellent manufacturability.

Although the disclosure has been made with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor light-emitting device comprising:
a substrate made of InP; and
an active layer that is positioned on the substrate, wherein
the active layer includes a Type-II heterojunction structure based on
a first-type layer made of AlₓIn_{y}Ga_{(1-x-y)}AS_{z}P_{(1-z)} (where 0<x, 0<y, 0≤1-x-y, and 0<z≤1 hold true), and
a second-type layer made of InᵥGa₍₁₋ᵥ₎AS_{w}P_{(1-w)} (where 0<v≤1 and 0≤w<1 hold true),
conduction band minimum energy of the second-type layer is lower than conduction band minimum energy of the first-type layer,
valence band maximum energy of the first-type layer is higher than valence band maximum energy of the second-type layer,
the first-type layer constitutes a quantum well layer for electron holes, and
the second-type layer constitutes a quantum well layer for electrons.

2. The semiconductor light-emitting device according to claim 1, wherein
the active layer performs light emission due to recombination of electrons of conduction band in the second-type layer and electron holes of valence band in the first-type layer that is spatially separated from the second-type layer, and
band gap in the first-type layer as well as band-gap in the second-type layer is greater than energy of the light emission.

3. The semiconductor light-emitting device according to claim 1, wherein the active layer includes a multiple quantum well structure in which the first-type layer and the second-type layer are alternately placed.

4. The semiconductor light-emitting device according to claim 3, wherein composition of the second-type layer varies in such a way that conduction band minimum energy decreases toward the first-type layer in layer thickness direction.

5. The semiconductor light-emitting device according to claim 3, wherein there are three of more of the second-type layer.

6. The semiconductor light-emitting device according to claim 1, wherein
the active layer further includes a pair of barrier layers that are made of AlᵣInₛGa₍₁₋ᵣ₋ₛ₎ASₜP₍₁₋ₜ₎ (where 0<r, 0<s, 0≤1-r-s, and 0≤t<1 hold true) having conduction band minimum energy to be higher than conduction band minimum energy of the first-type layer and having valence band maximum energy to be lower than valence band maximum energy of the second-type layer, and
the pair of barrier layers sandwich a Type-II heterojunction structure.

7. The semiconductor light-emitting device according to claim 1, wherein lattice constant of the first-type layer is greater than lattice constant of the substrate.

8. The semiconductor light-emitting device according to claim 7, wherein
lattice constant of the second-type layer is smaller than lattice constant of the substrate, and
in layering structure of the first-type layer and the second-type layer, thickness-weighted average strain is lower than 2%.

9. The semiconductor light-emitting device according to claim 1, wherein lattice constant of the first-type layer as well as lattice constant of the second-type layer is equal to lattice constant of the substrate.

10. The semiconductor light-emitting device according to claim 1, wherein the first-type layer is made of AlₓIn_{y}As.

11. The semiconductor light-emitting device according to claim 1, wherein the first-type layer is made of AlₓIn_{y}Ga_{(1-x-y)}As.
